(19) United States
(12) Patent Application Publication
(10) Pub. No.: US 2012/0275130 A1
(43) Pub. Date: Nov. 1, 2012

(54) ELECTRONIC DEVICE HOUSING AND METHOD OF MANUFACTURING THEREOF

(75) Inventors: MU-CHI HSU, Tu-Cheng (TW); SHAO-MING FU, Tu-Cheng, New Taipei (TW)

(73) Assignee: HON HAI PRECISION INDUSTRY CO., LTD., Tu-Cheng (TW)

(21) Appl. No.: 13/305,945

(22) Filed: Nov. 29, 2011

(30) Foreign Application Priority Data
Apr. 27, 2011 (TW) 100114717

(51) Int. Cl. H05K 7/02; B32B 38/16

(52) U.S. Cl. 361/807; 156/275.5

(57) ABSTRACT

An electronic device housing and a method of forming the housing are disclosed. The electronic device housing, comprises a bottom layer defining a though hole; an adhesion layer on the bottom layer defining a through hole; and a protection layer on the adhesion layer defining a through hole, wherein the adhesion layer is cured by ultraviolet (UV) rays, the adhesion layer is adapted to tightly combine the bottom layer and the protection layer.

### BACKGROUND

1. Technical Field

The present disclosure relates to a housing, and particularly, to an electronic device housing and a method of forming the housing.

2. Description of Related Art

Conventional housings for consumer electronic devices, such as mobile phones or tablet computers, are usually plastic and made by injection molding. To achieve the design appearance, the injected housings are usually painted with by spray processes. The paint is sprayed from a nozzle of a spray gun and is carried by high-speed air provided from the spray gun onto the housings. Since both the paint and air are sprayed with a high-pressure, the nozzle may need to be far enough away from the injected housings, or else the high-speed air may undesirably blow away the paint just coated on the housings. Thus, a nozzle spays too close to the housings may lead to uneven coatings on the housings. However, if the nozzle and the housings are kept at a certain distance to lower the spray speed, about 70% to 90% of the paint may not reach the housings and is thus wasted. Thus, known painting processes may not be environmentally friendly.

On the other hand, although plastic housings are easily formed, visual textures and touch of plastic housings may have appearances of cheap products; and may not appeal to users. In order to improve the texture of the product housings, some housings are made of metal. Metal housings may be polished to provide a brighter and smoother surface than plastic housings. Housings with metal textures are popular with users. However, surfaces of the metallic housing may easily scratched due to poor hardness of the metal. The longer the electronics are used, the more the metal housings get scratched. Over a long period, the housings may have unattractive appearances.

Accordingly, it is desirable to provide an electronic device housing and a method of forming the housing which may overcome the above described shortcomings.

### BRIEF DESCRIPTION OF THE DRAWINGS

Many aspects of the disclosure can be better understood with reference to the drawings. The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is a schematic, partial view of an electronic device housing according to a first embodiment of the present disclosure.

FIG. 2 is an exploded view of the electronic device housing of FIG. 1.

FIG. 3 is a cross section view of the electronic device housing of FIG. 1, taken along a cross line III-III.

FIG. 4 is a flowchart of a method of forming the electronic device housing of FIG. 1.

FIG. 5 is a partial, cross section view of an electronic device housing according to a second embodiment of the present disclosure.

FIG. 6 is a schematic, partial view of an electronic device housing according to a third embodiment of the present disclosure.

FIG. 7 is a schematic, partial view of an electronic device housing according to a fourth embodiment of the present disclosure.

FIG. 8 is a schematic, partial view of an electronic device housing according to a fifth embodiment of the present disclosure.

### DETAILED DESCRIPTION

Embodiments of the disclosure are now described in detail with reference to the accompanying drawings.

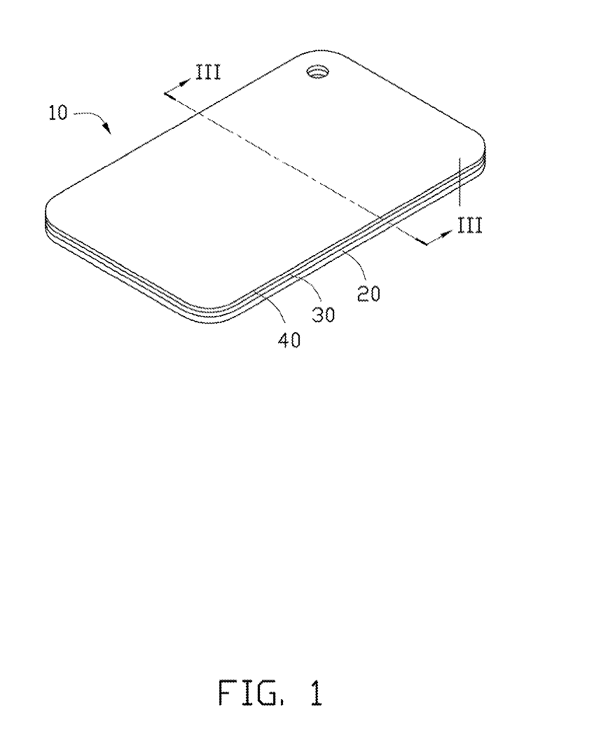

As shown in FIG. 1, the electronic device housing 10 of the present disclosure comprises a bottom layer 20, an adhesion layer 30, and a protection layer 40. The adhesion layer 30 is between the bottom layer 20 and the protection layer 40. In this embodiment, the electronic device housing 10 is a back cover of a mobile phone.

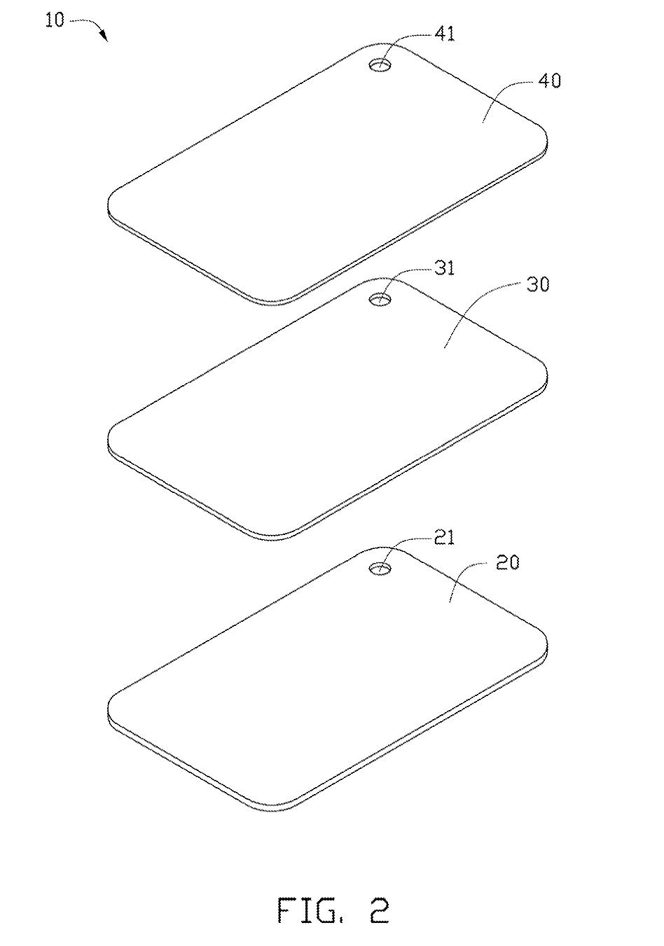

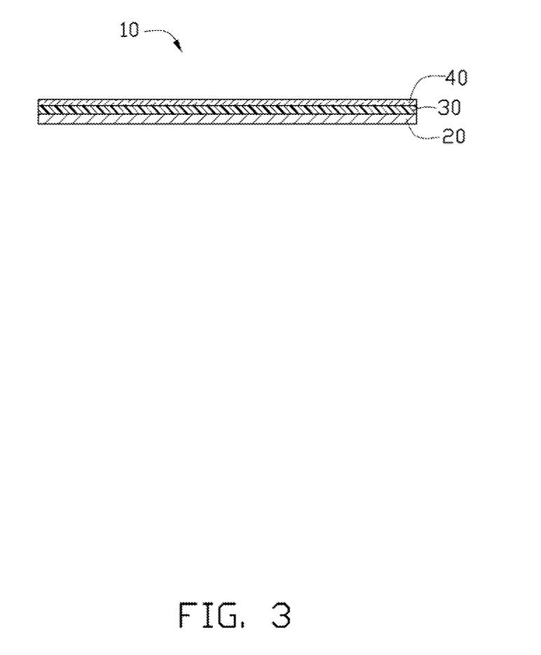

Referring to FIG. 2 and FIG. 3, the bottom layer 20 is located at the bottom of the electronic device housing 10 below. The bottom layer 20 covers and protects electronic components of an electronic device, such as circuits and a battery of a mobile phone (not shown), so the electronic components are not exposed to outside environment. In this embodiment, the bottom layer 20 is made from metal, such as stainless steel or aluminum alloy. The bottom layer 20 may be pretreated by one or more surface treatments, such as a polishing process, an etching process or an electroplating process.

The bottom layer 20 defines a through hole 21 corresponding to a camera module (not shown). The camera module may be located in the through hole 21, or behind the through hole 21.

The adhesion layer 30 covers an outer surface of the bottom layer 20. The outer surface is visible to users, and is opposite to the electronic components of the electronic device. The adhesion layer 30 is an ultraviolet (UV) curable adhesive, and defines a through hole 31 corresponding to the camera module (not shown). The through hole 31 is transparent after the adhesive layer is cured. In the current disclosure, an outer surface, an outer side, or an upper direction is a surface, a side, or a direction facing away from the electronic components in FIG. 1 through FIG. 3.

The protection layer 40 is on an outer side of the adhesion layer 30, opposite to the bottom layer 20. Accordingly, the adhesion layer 30 is sandwiched between the protection layer 40 and the bottom layer 20. The adhesion layer 30 is cured by ultraviolet (UV) rays, and is adapted to tightly combine the bottom layer 20 and the protection layer 40.

In this embodiment, the protection layer 40 is made of transparent glass, and defines a through hole 41 corresponding to the camera module (not shown). The camera module may be located in the through hole 41, or behind the through hole 41.

The bottom layer 20 is protected by the protection layer 40, and therefore may not be scratched or defaced. Accordingly, the outer surface of the bottom layer 20, visible to the users, may be kept bright and smooth, and the electronic device housing 10 has metallic luster on the bottom layer 20.

The protection layer 40 of transparent glass is harder than the bottom layer 20, so the electronic device housing 10 is difficult to be scratched. As a result, the electronic device housing 10 may maintain a new and glossy appearance.

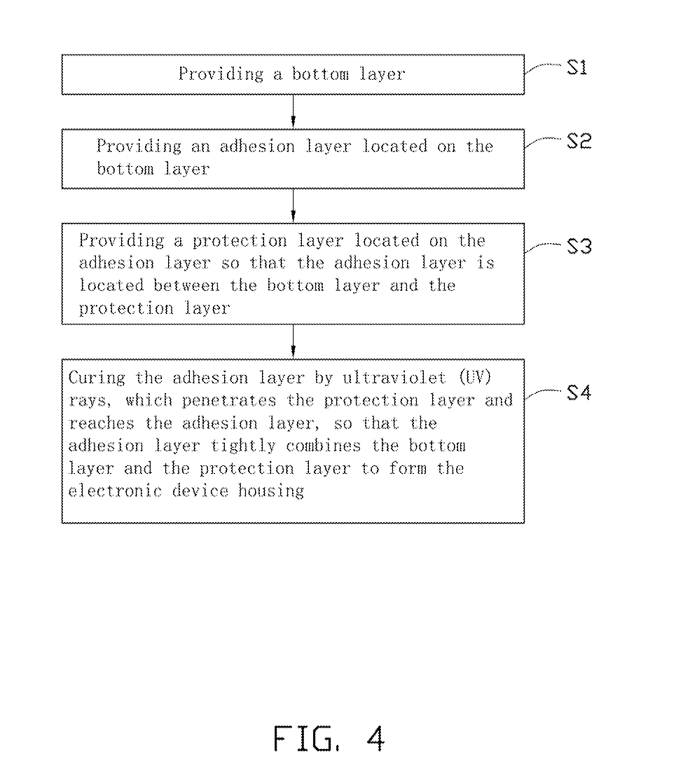

Referring to FIG. 4, wherein a method of forming an electronic device housing is shown. The method comprises steps of providing a bottom layer 20 in step S1. Providing an adhesion layer 30 on the bottom layer 20 in step S2; providing a protection layer 40 on the adhesion layer 30 in step S3 so that the adhesion layer 30 is between the bottom layer 20 and the protection layer 40. In step S4, the adhesion layer 30 is cured with UV rays, which penetrates the protection layer 40 and reaches the adhesion layer 30. The adhesion layer 30 tightly combines the bottom layer 20 and the protection layer 40. Forming of the electronic device housing 10 is complete.

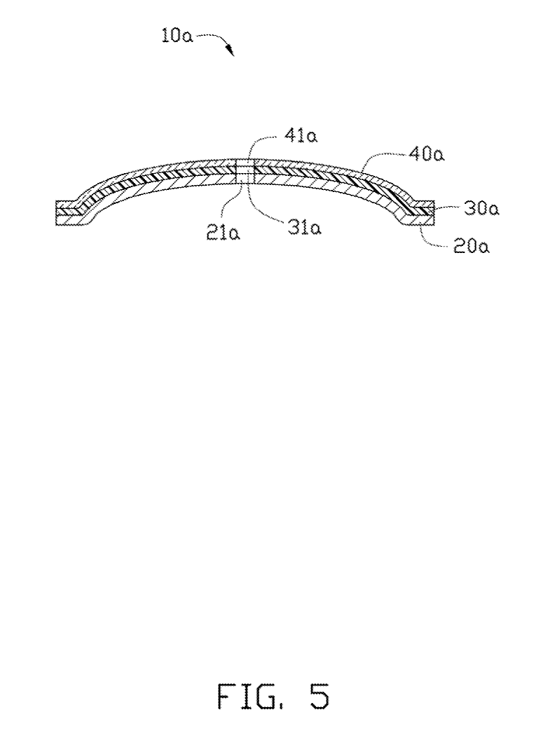

FIG. 5 illustrates a second embodiment of the present disclosure. The second embodiment is similar to the first embodiment, but has a different shape. An outline of a bottom layer 20a is not a flat plate as in the first embodiment, and an outer surface of the bottom layer 20a is a non-planar surface, such as a curved surface. Inner surfaces of an adhesion layer 30a and a protection layer 40a match the curved surface of the bottom layer 20a. The inner surface of the adhesion layer 30a is the surface contacting the bottom layer 20a, and the inner surface of the protection layer 40a is the surface contacting the adhesion layer 30a. Accordingly, an electronic device housing 10a may have a curved outer surface, a streamline outer surface, or any designed shape in the present disclosure. The bottom layer 20a, the adhesion layer 30a, and the protection layer 40a respectively define through holes 21a, 31a, and 41a corresponding to a camera module (not shown).

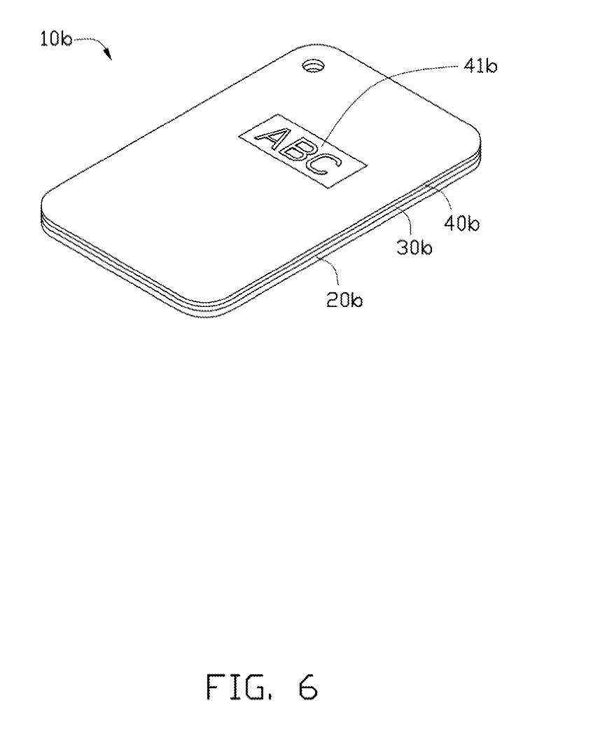

FIG. 6 illustrates a third embodiment of the present disclosure. The third embodiment is similar to the first embodiment, but also has a nameplate 41b. An electronic device housing 10b of the third embodiment further comprises a nameplate 41b inserted into the protection layer 40b. The nameplate 41b may be a name, a trademark, a brand, or any design.

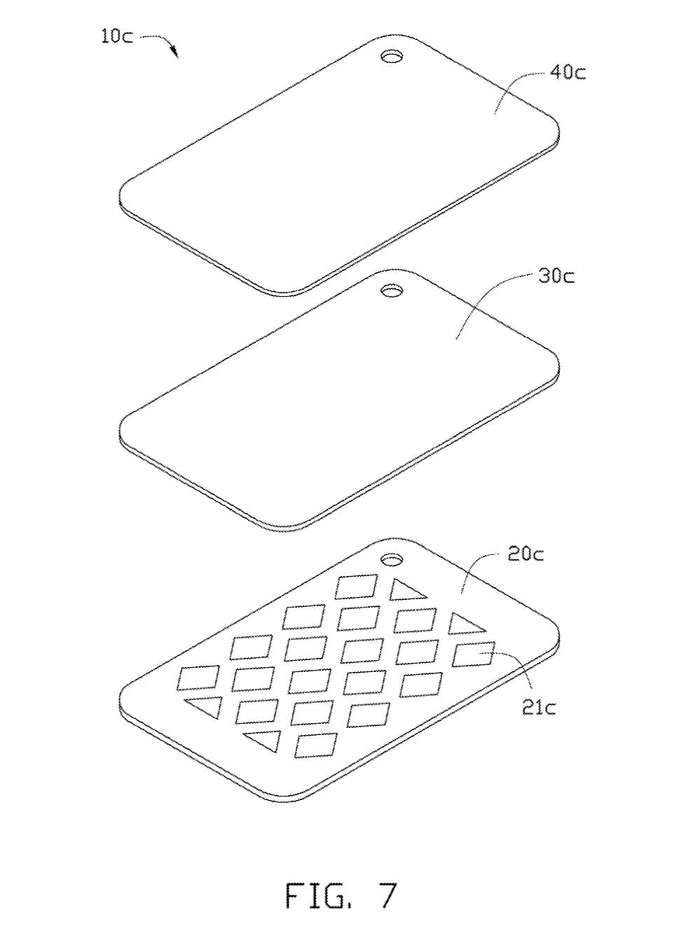

FIG. 7 illustrates a fourth embodiment of the present disclosure. The fourth embodiment is similar to the first embodiment, but has a bottom layer 20c having a plurality of through holes 21c. The bottom layer 20c of the fourth embodiment further defines a plurality of through holes 21c, which enables the users to see inner components.

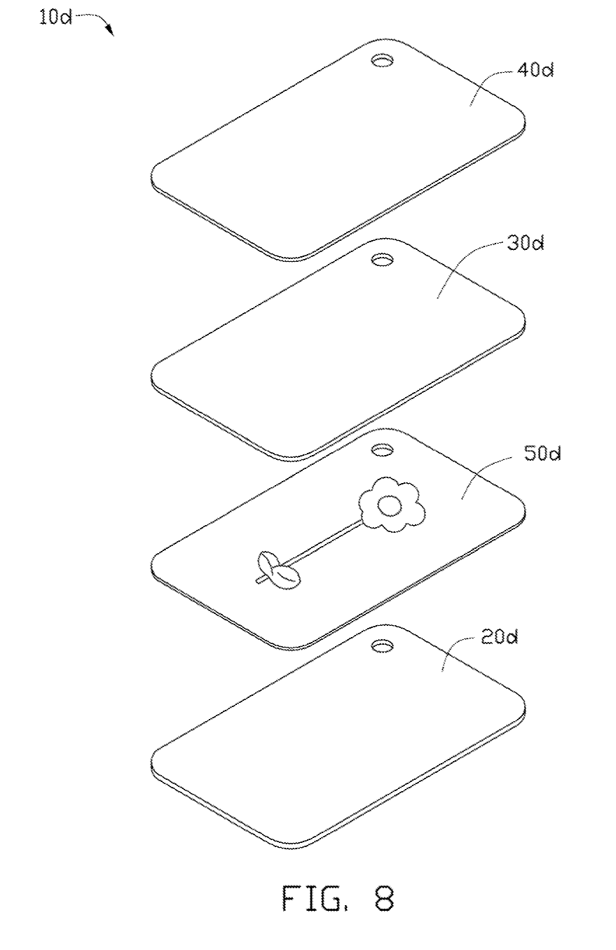

FIG. 8 illustrates a fifth embodiment of the present disclosure. The fifth embodiment is similar to the first embodiment, but has a decoration layer 50d between a bottom layer 20d and an adhesion layer 30d. The decoration layer 50d may be patterns or words with any designed colors, so to decorate an electronic device housing 10d.

It is to be understood, however, that even though numerous characteristics and advantages of the present embodiments have been set fourth in the foregoing description, together with details of the structures and functions of the embodiments, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. An electronic device housing, comprising:
a bottom layer defining a though hole;
an adhesion layer on the bottom layer defining a through hole; and
a protection layer on the adhesion layer defining a through hole, wherein the adhesion layer is cured by ultraviolet (UV) rays, the adhesion layer is adapted to tightly combine the bottom layer and the protection layer.

2. The electronic device housing of claim 1, wherein the bottom layer is selected from the group consisting of stainless steels, and aluminum alloys.

3. The electronic device housing of claim 2, wherein the bottom layer is pretreated by a surface treatment.

4. The electronic device housing of claim 1, wherein the protection layer is made of glass.

5. The electronic device housing of claim 1, wherein the adhesion layer is an UV curable adhesive.

6. The electronic device housing of claim 1, wherein the bottom layer comprises a non-planar surface.

7. The electronic device housing of claim 6, wherein the adhesion layer comprises an inner surface matching, and contacting the non-planar surface of the bottom layer.

8. The electronic device housing of claim 6, wherein the protection layer comprises an inner surface matching the non-planar surface of the bottom layer, and contacting the adhesion layer.

9. The electronic device housing of claim 1, wherein each of the through holes of the bottom layer, the adhesion layer, and the protection layer corresponds to a camera module.

10. The electronic device housing of claim 1, further comprising a nameplate inserted into the protection layer.

11. The electronic device housing of claim 1, wherein the bottom layer defines a plurality of through holes allowing a view of components under the electronic device housing.

12. The electronic device housing of claim 1, further comprising a decoration layer between the bottom layer and the adhesion layer, and the decoration layer bears patterns.

13. A method of forming an electronic device housing, comprising:
providing a bottom layer having a through hole;
providing an adhesion layer on the bottom layer having a though hole;
providing a protection layer having a through hole, on the adhesion layer so that the adhesion layer is between the bottom layer and the protection layer; and
combining the adhesion layer with the bottom layer and the protection layer to form the electronic device, wherein the combining comprises curing the adhesion layer by ultraviolet (UV) rays capable of penetrating the protection layer and reaching the adhesion layer so that the adhesion layer tightly adheres to the bottom layer and to the protection layer.

14. The method of claim 13, wherein the bottom layer is selected from the group consisting of stainless steels, and aluminum alloys.

15. The method of claim 13, further comprising pre-treating a surface of the bottom layer.

16. The method of claim 13, wherein the protection layer is made of glass, and the adhesion layer is an UV curable adhesive.

17. The method of claim 13, wherein the bottom layer comprises a non-planar surface;
the adhesion layer comprises an inner surface matching and contacting the non-planar surface of the bottom layer; and the protection layer comprises an inner surface matching the non-planar surface of the bottom layer, and contacting the adhesion layer.

18. The method of claim 13, further comprising inserting a nameplate into the protection layer.

19. The method of claim 13, wherein the bottom layer defines a plurality of through holes to provide views of components under the electronic device housing

20. The method of claim 13, further comprising providing a decoration layer between the bottom layer and the adhesion layer, wherein the decoration layer bears patterns.
